(19) United States
(12) Patent Application Publication
(10) Pub. No.: US 2003/0188243 A1
(43) Pub. Date: Oct. 2, 2003

(54) Method and apparatus for delay fault testing

(76) Inventor: Krishna B. Rajan, Newark, CA (US)

Correspondence Address: WILLIAM L. PARADICE, III, 425 CALIFORNIA STREET, SUITE 900, SAN FRANCISCO, CA, 94104, US

(21) Appl. No.: 10/113,365

(22) Filed: Mar. 29, 2002

(51) Int. Cl. G01R 31/28

(52) U.S. Cl. 714/731

(57) ABSTRACT

A TAP-controlled scan architecture is modified to include an additional pin to receive a double capture mode (DCM) signal that may be used to override a functional mode signal provided by a TAP controller to enable an externally generated functional clock to provide double capture clock pulses to an internal scan chain during testing without transitioning the TAP controller between states.

### BACKGROUND

1. Field of Invention

This invention relates generally to integrated circuit design and testing, and specifically to an improved method and apparatus of delay fault testing using a standard scan testing architecture.

2. Description of Related Art

Modern integrated circuits are tested for manufacturing defects as well as for operation and functional criteria. Manufacturing defects are characterized as those that prevent the circuit from properly implementing a desired function, and includes, for example, pins or signal lines that are “stuck” high or low. Process variations and defects inherent in the manufacturing of integrated circuits may result in delay faults that cause the circuit to not meet specified timing requirements such as, for example, failure to operate properly at a specified functional frequency.

Scan testing is a well-known technique that may be used to test for stuck-at fault defects arising from opens and/or short circuits during manufacturing. Scan testing is facilitated by serially connecting a plurality of scannable flip-flops in the integrated circuit to form a long shift register called a scan chain. A test pattern is clocked into the scan chain by activating a scan enable signal for all scannable flip-flops in the chain. The test pattern is typically supplied by a well-known automated testing equipment (ATE) device. After the test pattern is loaded into the scan chain, the scan enable signal is de-asserted, and a single clock pulse is applied to permit the functional result of the test pattern to be latched in the scannable flip-flops. The functional results of the test vector are then shifted out and compared with expected results to detect stuck-at faults.

Scan testing may also be used to detect delay faults arising from manufacturing process variations and gross timing defects. Detection of delay faults using scan testing requires two test patterns or vectors. The first test vector (commonly referred to as the V1 vector) is shifted into the scan chain to initialize the circuit to a known state, and the second test vector (commonly referred to as the V2 vector) propagates signal transitions through the circuit to determine whether an expected result reaches some observable point within a specified time period. For example, in a test methodology commonly known as functional justification delay testing, the scan enable signal is de-asserted after V1 is shifted into the scan chain, and a V2 clock pulse is asserted to generate V2 as the functional next state of V1. Then, a capture clock pulse is asserted to capture the functional results of V2 for timing observation. For successful at-speed testing, the V2 and capture clock pulses (also referred to herein as double capture clock pulses) are separated by the specified functional clock period.

Modern integrated circuits typically include testing architectures compliant with the standards promulgated by the Joint Test Access Group (JTAG). These standards are described in IEEE Standard Test Access Port and Boundary Scan Architecture 1149.1, incorporated by reference herein. Although originally intended for board-level testing such as, for example, detecting stuck-at faults of interconnections between interconnected chips on a board, the JTAG standard testing architecture may also be used to access testing features (e.g., scan chains) embedded within the core logic of the integrated circuits.

Certain limitations of the JTAG standard render at-speed functional justification delay testing impractical. Specifically, because the test clock provided by the JTAG testing architecture's test access port (TAP) controller is typically much slower than the functional clock speed of the integrated circuit, at-speed testing requires use of an external functional clock to generate the V2 and capture clock pulses. Unfortunately, the JTAG standard does not allow the TAP controller to provide externally generated V2 and capture clock pulses without transitioning between TAP controller states. Delays associated with transitioning between TAP controller states may cause the interval between assertion of the V2 and capture clock pulses to exceed the functional clock period. As a result, existing JTAG-compliant testing architectures are not able to provide the double capture clock pulses at the specified functional frequency, which in turn precludes successful at-speed testing.

### SUMMARY

A method and apparatus are disclosed that allow a TAP-controlled scan architecture to be used to implement at-speed functional justification delay testing. In accordance with the present invention, a TAP-controlled scan architecture is modified to include an additional pin to receive a double capture mode (DCM) signal that may be used to override a functional mode signal provided by a TAP controller to enable an externally generated functional clock to provide double capture clock pulses to an internal scan chain during testing without transitioning the TAP controller between states. In this manner, the double capture clock pulses, the first of which generates the V2 test vector from a previously loaded V1 test vector and the second of which generates the functional next state of the V2 test vector, are provided at the functional frequency to enable at-speed functional justification delay testing. By leveraging the TAP-controlled scan architecture to implement at-speed functional delay testing, additional testing architectures dedicated for functional justification delay testing may be eliminated, thereby reducing circuit size.

For one embodiment, the DCM signal and the functional mode signal are combined in a logic gate to generate a select signal for a multiplexer that selectively provides either the functional clock or a test clock to the internal scan chains for delay testing. The DCM signal is initially de-asserted so that the multiplexer is controlled by the functional mode signal provided by the TAP controller during testing. With the functional mode signal de-asserted to cause the multiplexer to provide the test clock to the internal scan chain, the first test vector (V1) is loaded into the scan chain using the test clock. After the V1 vector is loaded, the TAP controller is transitioned to a pause state. During the pause state, the DCM signal is asserted to cause the multiplexer to provide the functional clock to the internal scan chain, irrespective of the functional mode signal provided by the TAP controller, thereby overriding the functional mode signal. The functional clock provides the double capture clock pulses to implement at-speed functional justification delay testing while the TAP controller remains in the pause state. In this manner, present embodiments allow the externally generated functional clock to provide the double capture clock pulses without transitioning between TAP controller states.

### BRIEF DESCRIPTION OF THE DRAWINGS

The features and advantages of the present invention are illustrated by way of example and are by no means intended to limit the scope of the present invention to the particular embodiments shown, and in which:

FIG. 1 is a general block diagram of a conventional JTAG testing architecture within which embodiments of the present invention may be implemented;

FIG. 2 is a state diagram of the TAP controller for the JTAG architecture of FIG. 1;

FIG. 3 is a block diagram illustrating interconnections between the TAP controller and the internal logic of the circuit of FIG. 1;

FIG. 4 is a block diagram of a JTAG testing architecture supplemented in accordance with one embodiment of the present invention;

FIG. 5 is a flow chart illustrating operation of the testing architecture of FIG. 4; and

FIG. 6 is a timing diagram illustrating one embodiment of functional justification delay testing using the testing architecture of FIG. 4.

Like reference numerals refer to corresponding parts throughout the drawing figures.

### DETAILED DESCRIPTION

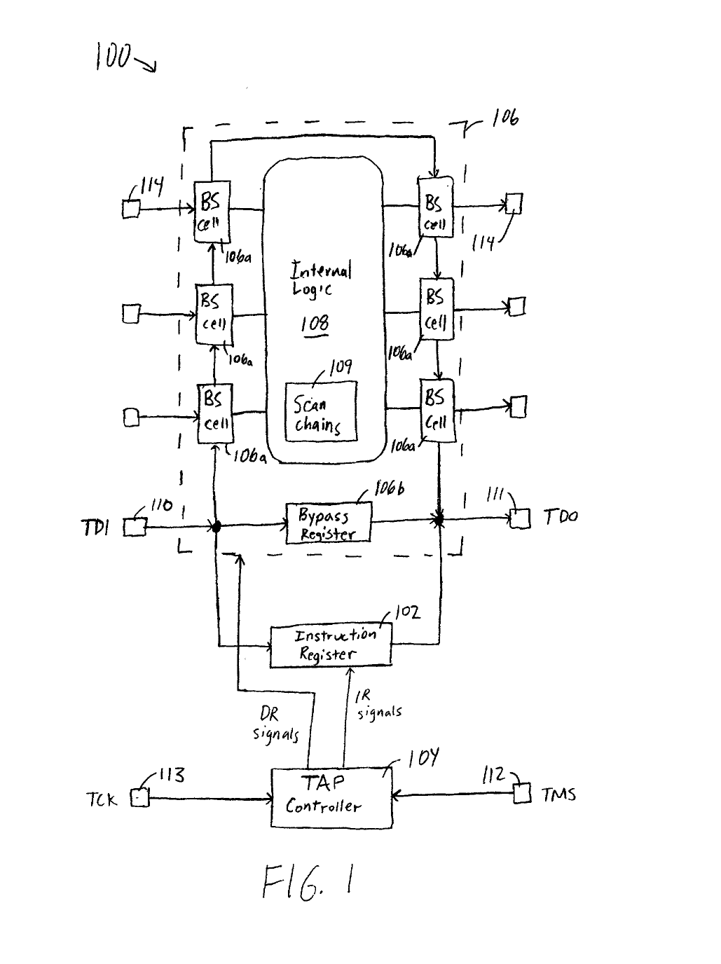

Referring to FIG. 1, a JTAG-compliant circuit 100 includes a single instruction register 102, a 16-state TAP controller 104, a set of test data registers 106 including boundary scan cells 106a and a bypass register 106b, and four test pins 110-113. In some embodiments, a fifth test pin (not shown for simplicity) may provide an optional test-reset signal to TAP controller 104.

Circuit 100 is also shown to include internal logic 108 that performs one or more specified functions. Internal logic 108 may include logic gates, memory elements, and/or other circuit components, and is shown to include an embedded scan chain 109. Scan chain 109 is well-known, and typically includes multiple scan chains, although scan chain 109 may be a single scan chain. Typically, the flip-flops that form each scan chain 109 include one or more multiplexers that, in response to a scan enable signal, allow the flip-flops to function either as part of internal logic 108 (e.g., during functional mode) or to form a scan chain that is independent of the internal logic 108 (e.g., during test mode). Further, although not shown for simplicity, internal logic 108 is coupled to receive an external system or functional clock via a clock pin.

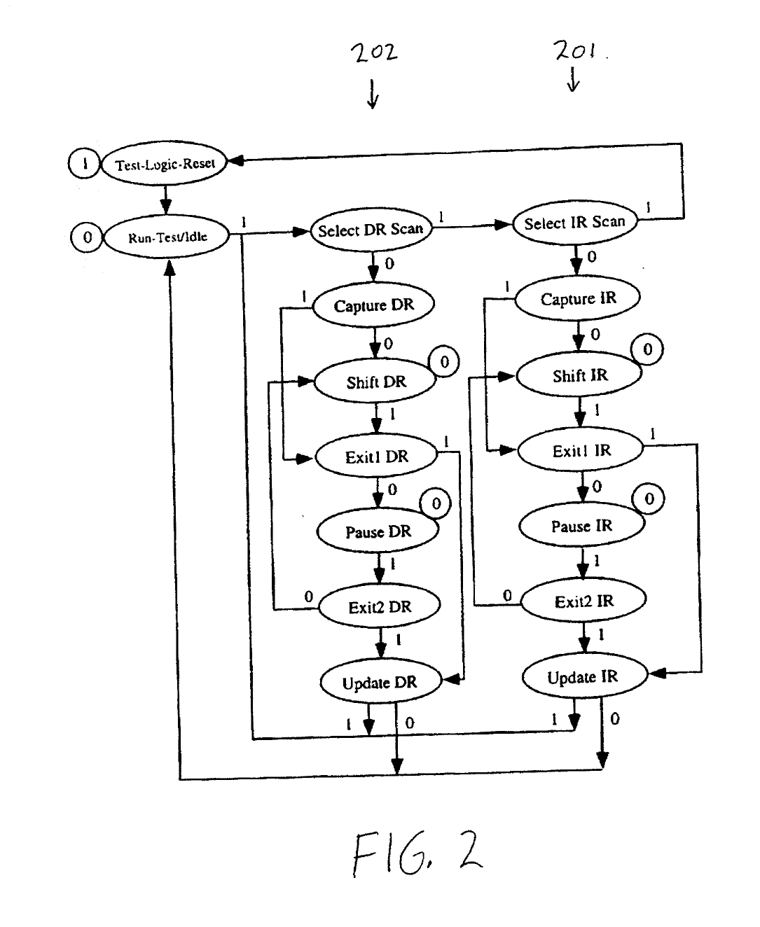

TDI pin 110 is the serial test input pin, TDO pin 111 is the serial test output pin, TMS pin 112 provides a test mode signal to TAP controller 104, and TCK pin 113 provides a test clock to TAP controller 104. The state transitions of TAP controller 104, which are illustrated in the state diagram of FIG. 2, are controlled by TCK and TMS in a well-known manner. During a first sequence 201 of state transitions, TAP controller 104 provides various signals to instruction register 102 to shift test instructions into instruction register 102 via TDI pin 110. During a second sequence 202 of state transitions, TAP controller 104 provides various signals to test data register 106, for example, to shift test data into data register 106 via TDI pin 110.

Boundary scan cells 106a are coupled in series to form a boundary scan register that may be selectively coupled between TDI pin 110 and TDO pin 111. Specifically, each boundary scan cell 106a includes a boundary scan input (BSI) coupled to the previous boundary scan cell and a boundary scan output (BSO) coupled to the next boundary scan cell, where the BSI of the first boundary scan cell is coupled to TDI pin 110 and the BSO of the last boundary scan cell is coupled to TDO pin 111. Each boundary scan cell 106a also includes a first data terminal coupled to a corresponding input/output (I/O) pin 114 and a second data terminal coupled to the internal logic 108 of circuit 100. In this manner, boundary scan cells 106a may selectively route signals between corresponding I/O pins 114 and internal logic 108 in a well-known manner. Bypass register 106b is coupled in parallel with the boundary scan register 106a, and may be used in a well-known manner to shift data unaltered between TDI pin 110 and TDO pin 111.

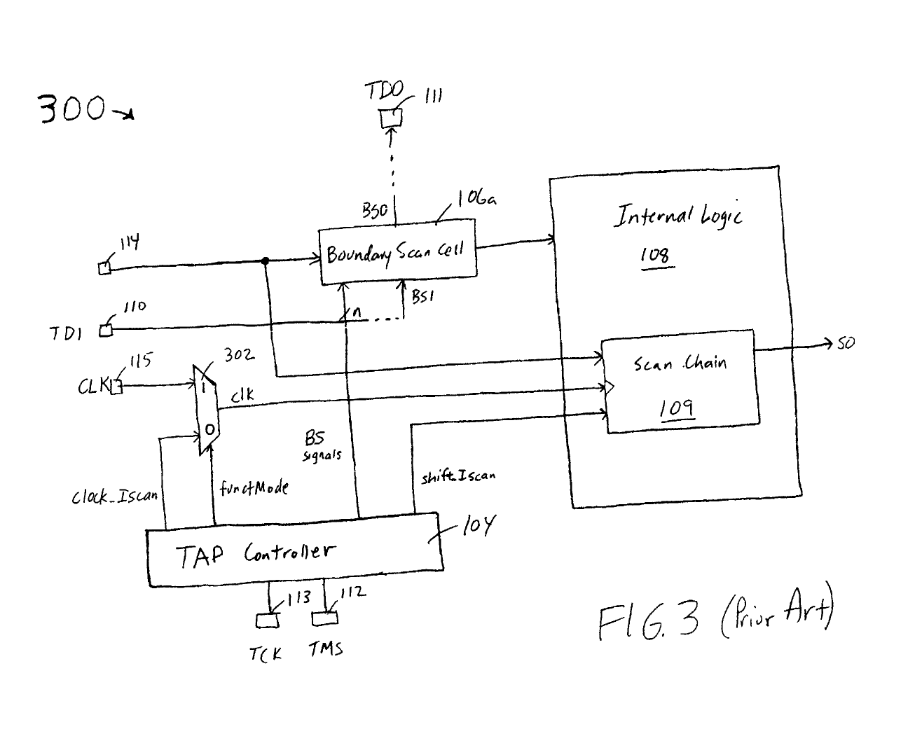

FIG. 3 shows conventional interconnections between TAP controller 104, one of input boundary scan cells 106a, and an internal scan chain 109 associated with the boundary scan cell 106a. I/O pin 114 is coupled to internal scan chain 109 and to corresponding boundary scan cell 106a. CLK is an externally generated functional or system clock provided to circuit 100 via clock pin 115. TAP controller 104 provides a number of well-known boundary scan (BS) signals to boundary scan cell 106a. These well-known BS signals include shift_Bscan, clock_Bscan, update_Bscan, select_jtag_input, and select_jtag_output. TAP controller 104 also generates signals clock_Iscan, functMode, and shift_Iscan. Signal shift_Iscan is provided to internal scan chain 109 as the scan enable signal. The clock signal clock_Iscan is a test clock derived from TCK, and typically operates at a lower frequency than the functional clock CLK. Signal functMode is a function mode signal that causes multiplexer (MUX) 302 to provide either the functional clock (CLK) or the test clock (clock_Iscan) to scan chain 109. For some embodiments, signal functMode indicates whether the circuit is in a functional mode or in a test mode.

During functional mode (e.g., non-test mode), TAP controller 104 remains in the Test-Logic-Reset state (see also FIG. 2), and asserts signal functMode (e.g., to logic high) so that the functional clock CLK is provided as the system clock to internal logic 108 via MUX 302. TAP controller 104 may also de-assert select_jtag_input (e.g., to logic low) so that boundary scan cell 106a routes input data provided at I/O pin 114 to internal logic 108, and may de-assert signal shift_Iscan (scan enable) so that the scannable flip-flops within scan chain 109 are de-coupled from the scan chain and coupled to functional elements of internal logic 108. For simplicity, the scannable flip-flops within scan chain 109 are not shown in the figures. While in the functional mode, the testing features associated with the JTAG testing architecture and internal scan chains 109 are transparent, and circuit 100 operates in a normal manner to perform its specified function(s).

During testing mode, after loading a test instruction, TAP controller 104 de-asserts functMode (e.g., to logic low) to indicate that circuit 100 is in test mode. While functMode is de-asserted, MUX 302 provides the test clock (clock_Iscan) from TAP controller 104 to internal logic 108. TAP controller 104 asserts select_Jtag_input (e.g., to logic high) to enable input boundary scan cells 106a , and asserts select_Jtag_out to enable output boundary scan cells 106a (only one input boundary scan cell is shown in FIG. 3 for simplicity). When enabled, boundary scan cells 106a are coupled between TDI pin 110, TDO pin 111, and internal logic 108, and may be used to load test stimulus into internal logic 108. The operation of TAP controller 104 and boundary scan cells 106a to detect static faults between interconnected circuits and within internal logic 108 is well-known, and therefore is not discussed in detail herein.

As mentioned above, the JTAG testing architecture shown in FIG. 3 is not well suited for functional justification delay testing because of certain constraints of the JTAG standard described in IEEE standard 1149.1. Specifically, TAP controller 104 allows for the application of only one capture pulse during the capture-DR state. Thus, in order to provide both V2 and capture clock pulses, TAP controller 104 transitions through state sequence 202 to switch between functional and testing modes, for example, by alternately asserting and de-asserting the signal functMode. However, as mentioned above, delays associated with transitioning through state sequence 202 of FIG. 2 in order to provide both the V2 and capture clock pulses for functional justification delay testing are typically greater than the functional clock period, which in turn precludes assertion of the V2 and capture clock pulses at the functional frequency. Because successful functional justification delay testing requires the V2 and capture clock pulses to be separated by the functional clock period, using the TAP-controlled scan architecture of FIG. 3 for functional justification delay testing is not feasible.

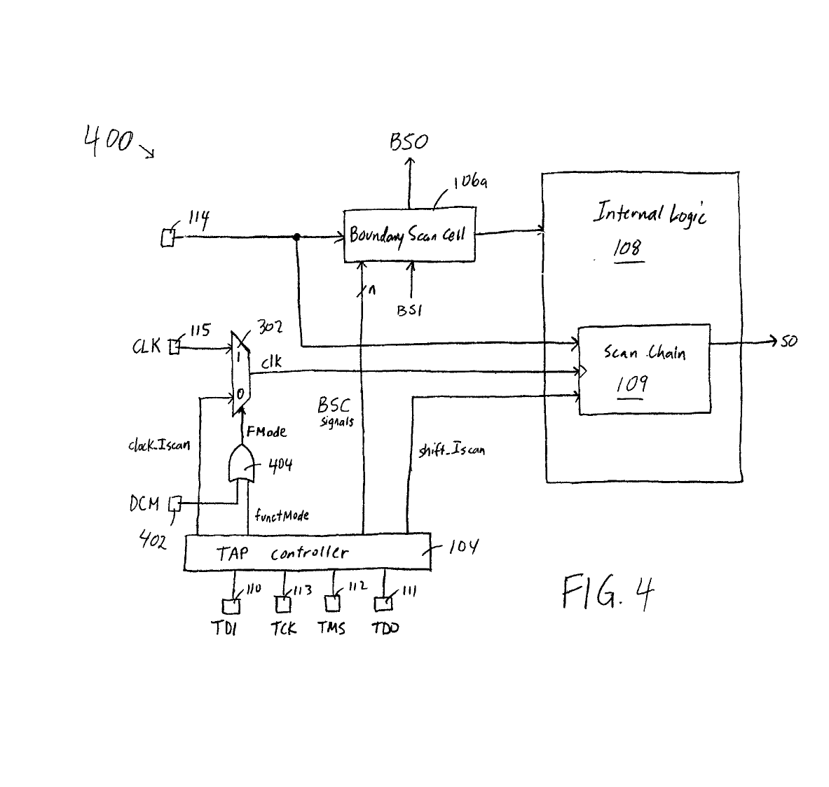

In accordance with the present invention, the JTAG testing architecture 300 of FIG. 3 is supplemented as shown in FIG. 4 to allow a TAP-controlled scan architecture to implement at-speed functional justification delay testing. The architecture 400 of FIG. 4 includes an additional I/O pin 402 to receive a double capture mode (DCM) signal and an OR gate 404 that together allow the functional clock CLK to provide the V2 and capture clock pulses for functional justification delay testing of internal logic 108 without transitioning between TAP controller states. For some embodiments, the frequency of functional clock CLK is the specified operating frequency of circuit 100. In one embodiment, the functional clock CLK is an externally generated system clock provided by well-known automated testing equipment (ATE), although other suitable clock generating means may be employed.

The DCM signal, which may be provided by the ATE or other suitable test circuitry, is coupled via pin 402 to a first input of OR gate 404. OR gate 404 has a second input coupled to receive the signal functMode from TAP controller 104, and has an output to provide a select signal FMode to the control terminal of MUX 302. In accordance with present embodiments, the DCM signal may be used to cause MUX 302 to provide the functional clock CLK to scan chain 109 by forcing the MUX control signal FMode to logic high regardless of the logic state of the signal functMode provided by TAP controller 104. Specifically, testing architecture 400 leverages the existing TAP controlled scan architecture to implement at-speed functional justification delay testing by allowing the functional clock CLK to provide the V2 and capture clock pulses without TAP controller 104 changing states. In this manner, separate testing circuitry dedicated for functional justification delay testing may be eliminated, thereby reducing circuit size and cost.

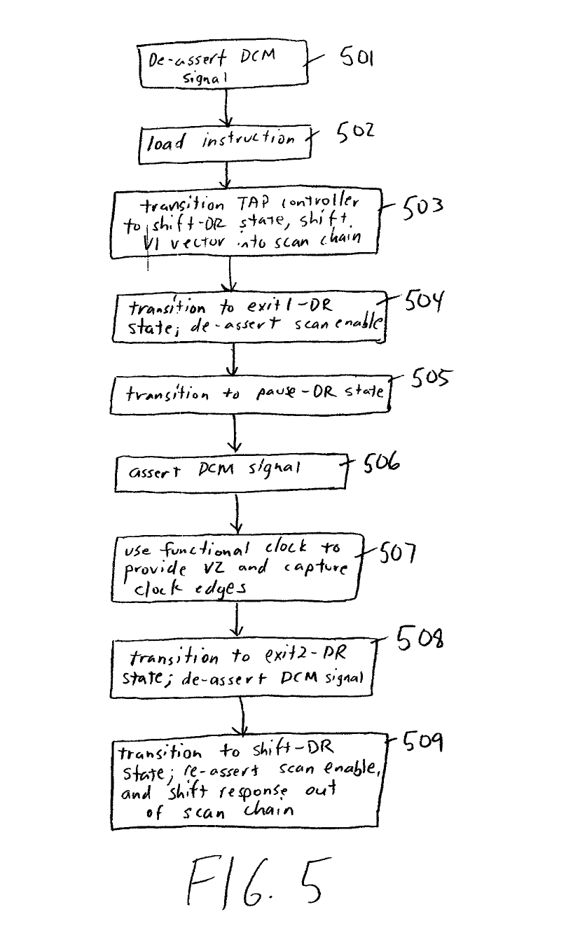

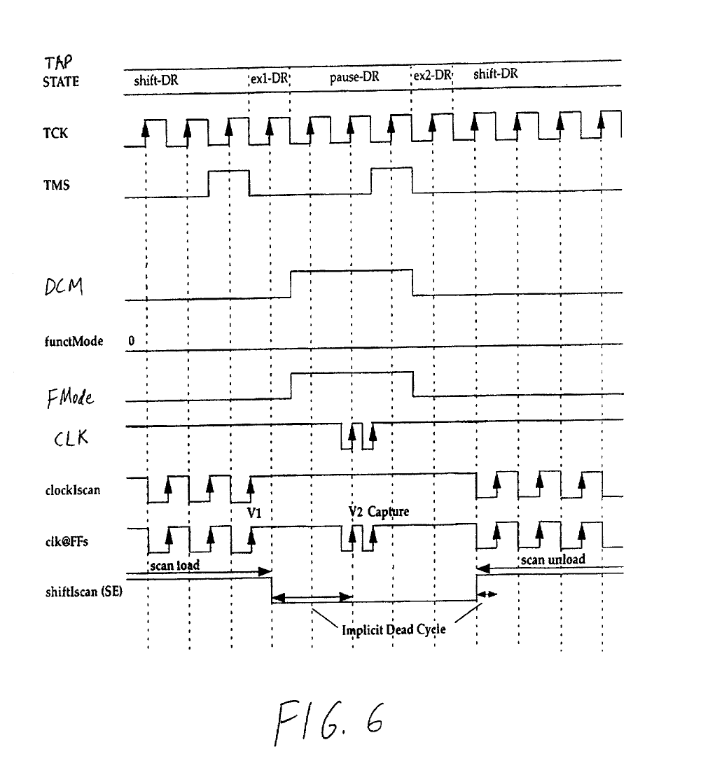

Operation of one embodiment of architecture 400 is described below with reference to the flow chart of FIG. 5 and to the timing diagram of FIG. 6, as well as to FIGS. 1 and 2. Initially, the DCM signal is de-asserted (e.g., to a logic low state) so that MUX 302 is controlled by the functMode signal provided by TAP controller 104 (step 501). Thus, when the DCM signal is de-asserted, the logic state of signal functMode is provided to the control terminal of MUX 302 via OR gate 404 to select whether the functional clock (CLK) or the test clock (clock_Iscan) is provided to internal logic 108. Circuit 400 may be put into delay test mode using TAP controller 104 and associated JTAG circuitry by loading a delay test instruction into instruction register 102 (step 502). For some embodiments, the delay test instruction may be loaded into instruction register (IR) 102 according to the well-known state sequence 201 of the state diagram of FIG. 2.

After the instruction is loaded into instruction register 102, TAP controller 104 transitions to the shift-DR state, and a first test vector V1 is shifted into scan chain 109 (step 503). The V1 vector may be generated using any suitable well-known technique including, for example, an automatic test vector generator (ATVG). For one embodiment, while in the shift-DR state, TAP controller 104 asserts the shift_Iscan (scan enable) signal to logic high, and the V1 vector is shifted into scan chain 109 using the test clock (i.e., clock_Iscan) provided by TAP controller 104 via MUX 302. The test clock is derived from TCK, and in some embodiments is slower than the functional clock CLK provided at pin 115, although any suitable test clock frequency may be used.

Then, TAP controller 104 transitions from the shift-DR state to the exit1-DR state and de-asserts the shift_Iscan (scan enable) signal (step 504). The exit1-DR state is a temporary state in which scannable flip-flops within scan chain 109 retain their current states. The scan enable (shift_Iscan) signal has ample time to settle during the exit1-DR state, thereby allowing for flexible dead cycles as illustrated in FIG. 6. These dead cycles allow the V1 vector to settle, even where there are timing faults. Then, TAP controller 104 transitions to the pause-DR state (step 505). The pause-DR state is typically used to halt the current scan operation.

In accordance with one embodiment of the present invention, the DCM signal is asserted to logic high while TAP controller 104 remains in the pause-DR state (step 506). The asserted DCM signal causes MUX 302 to provide the functional clock CLK to scan chain 109, irrespective of the state of signal functMode, thereby overriding the functMode signal. In this manner, the functional clock CLK is provided to scan chain 109 without TAP controller 104 transitioning between states and without TAP controller 104 asserting the signal functMode.

With TAP controller 104 in the pause-DR state and the DCM signal forcing MUX 302 to provide the functional clock CLK to scan chain 109, the functional clock CLK may provide the double capture clock pulses (i.e., the V2 and capture clock pulses) for functional justification delay testing of internal logic 108 (step 507). Specifically, a first functional clock pulse provides the V2 clock pulse to scan chain 109 to generate the V2 vector as the functional next state or response of the V1 vector. A second functional clock pulse provides the capture clock to scan chain 109 to capture the functional response of the V2 vector.

Once the functional response of the V2 vector is captured in scan chain 109, TAP controller 104 transitions to the exit2-DR state, and the DCM signal is de-asserted (step 508). The de-asserted DCM signal allows MUX 302 to again be controlled by the signal functMode, which in its de-asserted state causes MUX 302 to provide the test clock (clock_Iscan) to scan chain 109. TAP controller 104 then transitions to the shift-DR state and re-asserts the shift_Iscan (scan enable) signal (step 509). The results of the captured response of the V2 vector may then be shifted out of scan chain 109 using the test clock (clock_Iscan) (step 510).

As explained above, testing architecture 400 of the present invention allows associated TAP controller 104 to maintain signal functMode in a de-asserted state while allowing the functional clock CLK to provide the double capture clock pulses to internal logic 108. Because the functional clock CLK operates at the specified clock frequency of circuit 400, the resultant V2 and capture clock pulses are separated by the functional clock period. In this manner, present embodiments leverage the TAP controlled scan architecture to implement at-speed functional justification delay testing, which in turn eliminates the need for additional circuitry dedicated for implementing at-speed functional justification delay testing, thereby advantageously reducing circuit size and complexity.

The architecture 400 described above may be used to implement other testing methodologies (e.g., stuck-at fault testing) in accordance with the JTAG standard embodied in IEEE 1149.1. Further, embodiments of the present invention may be implemented in circuits with or without built-in self test (BIST) architectures. Thus, for those embodiments for which internal logic 108 does not include a BIST architecture, testing architecture 400 allows for implementation of at-speed delay tests by leveraging existing TAP controller 104 and associated JTAG circuitry. In those embodiments for which internal logic 108 includes a BIST architecture, testing architecture 400 may provide redundant at-speed delay test capabilities that may be useful, for example, if the BIST architecture is defective.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A testing architecture for implementing at-speed functional justification delay testing of an integrated circuit having a scan chain, comprising:
a test access port (TAP) controller configured as a finite state machine, the TAP controller generating a test clock and generating a function mode signal that selects whether the circuit operates in a functional mode or in a test mode;
an externally generated functional clock that operates at a specified functional frequency of the circuit; and
means for allowing the functional clock to provide double capture clock pulses to the scan chain during testing of the circuit without transitioning the TAP controller between states.

2. The testing architecture of claim 1, wherein the TAP controller comprises a JTAG compliant TAP controller.

3. The testing architecture of claim 2, wherein the TAP controller remains in a pause state during application of the double capture clock pulses to the scan chain.

4. The testing architecture of claim 3, wherein the means for allowing comprises:
a mode pin to receive a double capture mode signal;
a multiplexer having a first input to receive the functional clock, a second input to receive the test clock, an output coupled to the scan chain, and a control terminal; and
a logic gate having an first input to receive the double capture mode signal, a second input to receive the function mode signal from the TAP controller, and an output coupled to the control terminal of the multiplexer.

5. The testing architecture of claim 4, wherein the logic gate comprises an OR gate.

6. The testing architecture of claim 4, wherein the double capture clock pulses comprise first and second clock pulses, wherein:
the first clock pulse generates a second test vector as a functional response of a first test vector previously loaded into the scan chain; and
the second clock pulse captures a functional response of the second test vector.

7. A testing architecture for implementing at-speed delay testing of an integrated circuit having a scan chain, comprising:
a test access port (TAP) controller configured as a finite state machine, the TAP controller generating a test clock and generating a function mode signal that selects whether the circuit operates in a functional mode or in a test mode;
a clock pin to receive a functional clock operating at a specified functional clock frequency of the circuit;
a multiplexer having a first input to receive the functional clock, a second input to receive the test clock, and an output coupled to a clock input of the scan chain; and
means for selectively providing multiple cycles of the functional clock to the scan chain without transitioning the TAP controller between states.

8. The testing architecture of claim 7, wherein the TAP controller comprises a JTAG compliant TAP controller.

9. The testing architecture of claim 8, wherein the TAP controller remains in a pause state when the means for providing provides the functional clock to the scan chain.

10. The testing architecture of claim 8, wherein the TAP controller provides a scan enable signal to the scan chain.

11. The testing architecture of claim 7, wherein the multiple cycles of the functional clock comprise first and second clock pulses, wherein:
the first clock pulse generates a second test vector as a functional response of a first test vector previously loaded into the scan chain; and
the second clock pulse captures a functional response of the second test vector.

12. The testing architecture of claim 7, further comprising:
means for loading the first test vector into the scan chain.

13. The testing architecture of claim 12, wherein the means for loading comprises a boundary scan register.

14. The testing architecture of claim 7, wherein the functional clock is generated externally by an automatic testing device.

15. The testing architecture of claim 7, wherein the means for providing comprises:
a mode pin to receive a double capture mode signal; and
a logic gate having a first input to receive the double capture mode signal, a second input to receive the function mode signal from the TAP controller, and an output coupled to a control terminal of the multiplexer.

16. The testing architecture of claim 15, wherein the logic gate comprises an OR gate.

17. The testing architecture of claim 15, wherein the multiplexer routes the test clock from the TAP controller to the scan chain when the double capture mode signal is in a de-asserted state.

18. The testing architecture of claim 15, wherein the multiplexer routes the functional clock to the scan chain when the double capture mode signal is in an asserted state, irrespective of the function mode signal.

19. A method of testing an integrated circuit having a scan chain for at-speed delay faults using a JTAG compliant test access port (TAP) controller, the method comprising:
providing an externally generated functional clock to the circuit, the functional clock having a frequency equal to the specified functional frequency of the circuit;
transitioning the TAP controller to a shift state;
shifting a first test vector into the scan chain;
transitioning the TAP controller to a pause state; and
providing first and second pulses of the functional clock to the scan chain while the TAP controller remains in the pause state, the first pulse generating a second test vector as the functional response of the first test vector, the second pulse capturing the functional response of the second test vector.

20. The method of claim 19, further comprising:
asserting a double capture mode signal that overrides a functional mode signal generated by the TAP controller.

21. A method of testing an integrated circuit having a scan chain for at-speed delay faults using a JTAG compliant test access port (TAP) controller, the method comprising:
de-asserting a functional mode signal provided by the TAP controller to place the circuit in a test mode;
shifting a first test vector into the scan chain using a test clock provided by the TAP controller;
providing an externally generated functional clock to the circuit, the functional clock having a frequency equal to the specified functional frequency of the circuit; and
allowing the functional clock to provide double capture clock pulses to the scan chain while the function mode signal remains de-asserted, the double capture clock signals comprising:
a first clock pulse for generating a second test vector as a functional response of the first test vector; and
a second clock pulse for capturing a functional response of the second test vector.
